(19) United States
(12) Patent Application Publication
(10) Pub. No.: US 2013/0009193 A1
(43) Pub. Date: Jan. 10, 2013

(54) METHOD OF FABRICATING LIGHT RECEIVING ELEMENT AND APPARATUS FOR FABRICATING LIGHT RECEIVING ELEMENT

(76) Inventors: Motoichi Ohtsu, Bunkyo-ku (JP); Tadashi Kawazoe, Bunkyo-ku (JP); Takashi Yatsui, Bunkyo-ku (JP); Sotaro Yukutake, Bunkyo-ku (JP)

(21) Appl. No.: 13/511,734

(22) PCT Filed: Nov. 24, 2010
(86) PCT No.: PCT/JP2010/006858

§ 371 Date: Sep. 24, 2012

(30) Foreign Application Priority Data
Nov. 25, 2009 (JP) 2009-267811

(51) Int. Cl. H01L 31/0224; C23C 14/46; H01L 31/02

(52) U.S. Cl. 257/99; 438/57; 438/98; 204/298.04; 257/E31.124; 257/E31.11

(57) ABSTRACT

A method of fabricating a light receiving element includes depositing a material for one of a P-type semiconductor, an N--type semiconductor, and electrodes, while applying a reverse bias voltage and irradiating light of a desired wavelength longer than an absorption wavelength of the material. The deposition has a non-adiabatic flow of, at a portion where a local shape to enable generation of near field light is formed on a surface of the deposited material with the irradiation light, absorbing the irradiation light through a non-adiabatic process with the near field light, thereby generating electrons, and canceling generation of a local electric field based on the voltage, and a particle adsorbing flow of, at a portion where the shape is not formed, causing the portion where the local electric field is generated to sequentially adsorb particles forming the material, and shifting to the non-adiabatic flow when the shape is formed.

### TECHNICAL FIELD

The present invention relates to a method of fabricating a light receiving element, a method of easily fabricating a light receiving element without selecting a material for the light receiving element provided with a sensitivity to a specific wavelength, and an apparatus for fabricating a light receiving element.

### BACKGROUND ART

A light receiving element receives light with a depletion layer formed by application of a reverse bias voltage to the PN junction. The light which has entered the light-receiving surface of the light receiving element is absorbed in a field of a small energy band called a light absorption layer, generating a carrier in the light absorption layer. The carrier produced by optical absorption is accelerated by the internal electric field gradient based on the applied reverse bias voltage, and is detected as an electrical signal.

By the way, to provide the light receiving element with a sensitivity to a certain specific wavelength, it is necessary to select a material with a band gap smaller than that of the photon energy based on that wavelength. However, while multifarious and advanced social demands, such as application of the optical technology to security, in the modern society are increasing, there are various demands regarding the receivable wavelengths. For the reason, to newly set a wavelength which is sensitive to a light receiving element, or to change the wavelength which is sensitive to the light receiving elements which have been fabricated conventionally to another wavelength, a material needs to be selected every time, thus increasing the burden on the fabrication work. Accordingly, there has been a need for fabrication technology that easily can fabricate a light receiving element without selecting a material for an element provided with a sensitivity to specific wavelength.

In addition, due to the limited material technology, the wavelength range which can be provided with a sensitivity to light to be received is limited for the light receiving elements which have been proposed so far. Even in a case where light with a wavelength which cannot be photoelectrically converted is input to such a conventional light receiving element, if photoelectric conversion of the light is possible, it is possible to cope with various needs on receivable wavelengths.

In recent years, there has been proposed a technique of detecting only near field light which is not sensitive to propagation light using a non-adiabatic process with near field light as disclosed in Non-patent Document 1. However, the technique disclosed in Non-patent Document 1 is not focused on how to easily fabricate a light receiving element which is not sensitive to a specific wavelength without selecting a material therefor.

### PRIOR ART DOCUMENT

### Non-Patent Document

[Non-patent Document 1] T. Kawazoe, K. Kobayashi, S. Takubo, and M. Ohtsu, J. Chem. Phys., Vol. 122, No. 2, January 2005, pp. 024715 1-5

### SUMMARY OF THE INVENTION

### Problem to be Solved by the Invention

Accordingly, the present invention has been devised in view of the above-mentioned problems, and it is an object of the invention to provide a method of easily fabricating a light receiving element provided with a sensitivity to a specific wavelength without selecting a material for the element, and an apparatus for fabricating a light receiving element.

### Means for Solving the Problems

A method of fabricating a light receiving element described in claim 1 of the present application is characterized in that in order to solve the above problems in a method of fabricating a light receiving element with a PN junction of a P-type semiconductor and an N-type semiconductor joined together, and electrodes connected to the P-type semiconductor and the N-type semiconductor, respectively, the method includes a deposition step of depositing a material for one of the P-type semiconductor, the N-type semiconductor and the electrodes while applying a reverse bias voltage and irradiating light of a desired wavelength longer than an absorption wavelength of the material to be deposited, the deposition step having a non-adiabatic flow of, at a portion where a local shape to enable generation of near field light is formed on a surface of the deposited material with irradiation light of the desired wavelength, absorbing the irradiation light of the desired wavelength through a non-adiabatic process with the near field light generated in the local shape, thereby generating electrons, and canceling generation of a local electric field based on the reverse bias voltage in the local shape with the generated electrons in succession, and a particle adsorbing flow of, at a portion where the local shape is not formed, causing the portion where the local electric field based on the reverse bias voltage is generated to sequentially adsorb particles forming the material, and shifting to the non-adiabatic flow when the local shape is formed through the adsorption process.

A method of fabricating a light receiving element described in claim 2 of the present application is characterized in that in the invention according to claim 1, the non-adiabatic flow and the particle adsorbing flow are continuously performed to sequentially form the local shape on the surface of the deposited material.

A light receiving element described in claim 3 of the present application is characterized in that the light receiving element is fabricated by the fabrication method of the light receiving element according to claim 1 or claim 2.

An apparatus for fabricating a light receiving element described in claim 4 of the present application is characterized in that in an apparatus for fabricating a light receiving element with a PN junction of a P-type semiconductor and an N-type semiconductor joined together, and electrodes connected to the P-type semiconductor and the N-type semiconductor, respectively, the apparatus includes a voltage application means that applies a reverse bias voltage, and a deposition means that deposits a material for one of the P-type semiconductor, the N-type semiconductor and the electrodes while irradiating light of a desired wavelength longer than an absorption wavelength of the material to be deposited, the deposition means performing a non-adiabatic flow of, at a portion where a local shape to enable generation of near field light is formed on a surface of the deposited material with irradiation light of the desired wavelength, absorbing the irradiation light of the desired wavelength through a non-adiabatic process with the near field light generated in the local shape, thereby generating electrons, and canceling generation of a local electric field based on the reverse bias voltage in the local shape with the generated electrons in succession, and a particle adsorbing flow of, at a portion where the local shape is not formed, causing the portion where the local electric field based on the reverse bias voltage is generated to sequentially adsorb particles forming the material, and shifting to the non-adiabatic flow when the local shape is formed through the adsorption process.

### Effect of the Invention

According to the invention with the above-described configurations, it is possible to easily fabricate a light receiving element which is provided with a sensitivity to a specific wavelength without selecting a material for the element.

### BRIEF DESCRIPTION OF THE DRAWINGS

FIG. 1 is a diagram showing the configuration of a sputtering system for achieving a method of fabricating a light receiving element to which the invention is applied.

FIG. 2 is a diagram showing the detailed configuration of a light receiving element to be actually placed on a table.

FIG. 3 is a diagram showing the microscopic state of the surface of a material for an N-type semiconductor at the time of depositing the material by sputtering.

FIG. 4 is a conceptual diagram of the potential energy of a material for an N-type semiconductor.

FIG. 5 shows diagrams of a model in which the bonding of atoms is shown in terms of springs for explaining a non-adiabatic process.

FIG. 6 shows diagrams illustrating a case where a non-adiabatic flow and a particle adsorbing flow are continuously performed.

FIG. 7 is a diagram for explaining a light receiving process using a non-adiabatic process.

FIG. 8 is a diagram showing the wavelength dependency on the photoelectric current of a light receiving element fabricated by the fabrication method to which the invention is applied.

### MODE FOR CARRYING OUT THE INVENTION

Hereafter, an embodiment of the invention is described in detail.

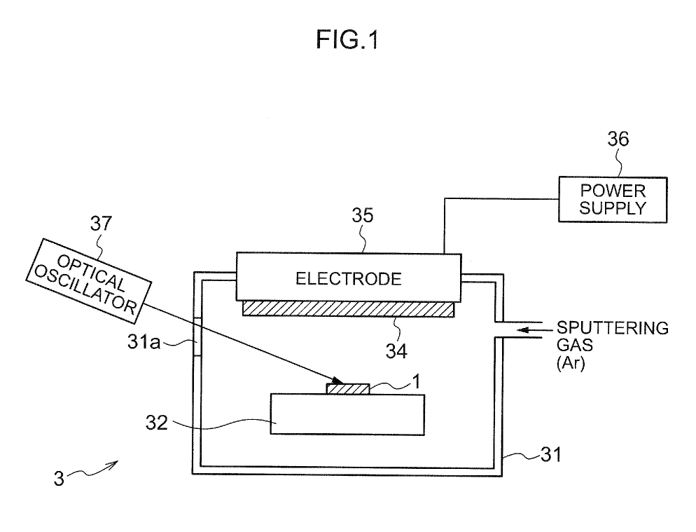

FIG. 1 shows the configuration of a sputtering system 3 for achieving a method of fabricating a light receiving element to which the invention is applied.

The sputtering system 3 is configured to include a chamber 31, a table 32 for mounting a light receiving element 1, a target 34 disposed on the opposite side to the light receiving element 1, and an electrode 35 to which the target 34 is attached. The table 32, the target 34 and the electrode 35 are disposed in the chamber 31. The sputtering system 3 further includes, outside the chamber 31, a power supply 36 connected to the electrode 35, and an optical oscillator 37 disposed on a side or the like of the chamber 31.

In the sputtering system 3, after exhausting the inside of the chamber 31 to about 10⁻² Torr, inactive gas, such as Ar, is introduced, and a voltage is applied to the electrode from the power supply 36 to cause discharging. This makes it possible to create a plasma state in the vicinity of the surface of the target 34. Since the potential of the generated plasma is usually higher than that of the surface of the target 34, a DC electric field is produced between the plasma and the target 34. Positive ions, such as Ar⁺ ions, in the inactive gas are accelerated by the produced electric field, collide on the surface of the target 34, resulting in sputtering so that minute particles on the target 34 are emitted sequentially. Incidentally, the emitted minute particles will be deposited on the light receiving element 1 without colliding with the molecules of the inactive gas.

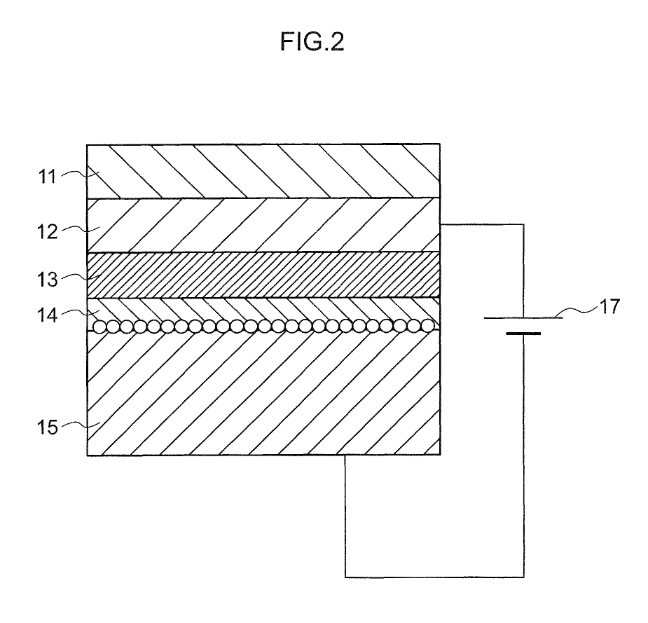

FIG. 2 shows the detailed configuration of the light receiving element 1 to be actually placed on the table 32. This light receiving element 1 includes a first electrode 12 stacked on a substrate 11, an N-type semiconductor 13 connected to the first electrode 2, a P-type semiconductor 14 which forms a PN junction with the N-type semiconductor 13, and a second electrode 15 connected to the P-type semiconductor 14. A power supply 17 is connected to the first electrode 12 and the second electrode 15 to apply a load of a reverse bias voltage with the N type side serving as a positive voltage and the P type side serving as a negative voltage.

The substrate 11 is formed of a substrate that is called sapphire, silicon, or the like.

The first electrode 12 includes a transparent electrode or the like; for example, it may be made of ITO (Indium Tin Oxide). The second electrode 15 may be made of Ag or the like. It is to be noted that the materials for the first electrode 12 and the second electrode 15 are not limited to those mentioned, and any material may be used.

A semiconductor represented by, for example, ZnO, In₂O₃, SnO₂, or the like may be used for the N-type semiconductor 13. The P-type semiconductor 14 may be made of polythiophene (P3HT) or the like. It is to be noted that the N-type semiconductor 13 and P-type semiconductor 14 which form the PN junction are not limited to those mentioned, and any material may be used for the semiconductors.

The power supply 17 includes a stabilization DC power supply, a cell, etc.

According to the light receiving element fabricating method to which the invention is applied, a material for one of the P-type semiconductor 14, N-type semiconductor 13, and each electrode 12, 15 is deposited by sputtering. In the deposition step, light with a longer wavelength than the absorption wavelength of the material to be deposited is emitted from the optical oscillator 37 while applying a reverse bias voltage to the PN junction formed by the P-type semiconductor 14 and N-type semiconductor 13. The light emitted by the optical oscillator 37 is led to the light receiving element 1 via a window 31a. Hereafter, the wavelength of the light emitted by the optical oscillator 37 is called “desired wavelength”.

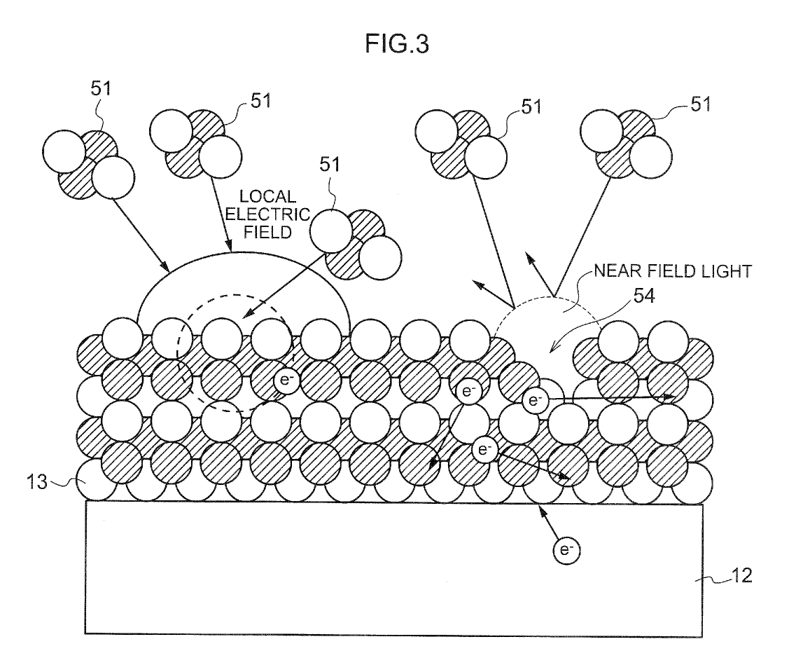

The following explains a case of depositing the material by sputtering for the N-type semiconductor 13 among the P-type semiconductor 14, N-type semiconductor 13, and the electrodes 12, 15 of the light receiving element 1 by way of example. FIG. 3 shows the microscopic state of the surface of the material for the N-type semiconductor 13 at the time of depositing the material by sputtering.

A local electric field based on the reverse bias voltage is produced on the surface of the N-type semiconductor 13. Particles 51 which constitute the material for the N-type semiconductor 13 are sequentially adsorbed to the portion where the local electric field is produced. Through the adsorption process, the material is sequentially deposited on the surface of the N-type semiconductor 13. The flow of sequentially adsorbing the particles 51 on the local electric field is hereafter called “particle adsorbing flow”.

There is a case where the local shape 54 shown in FIG. 3, for example, is formed accidentally in the process of carrying out such sputtering deposition. This local shape 54 can generate near field light more effectively when the light of the desired wavelength mentioned above is irradiated.

The local shape 54 which can generate the near field light varies with the wavelength of the irradiated light. Accordingly, when the desired wavelength is changed, naturally the local shape 54 which can generate near field light also varies. That is, the local shape 54 is unique to every desired wavelength.

When the local shape 54 which can generate near field light effectively with respect to the desired wavelength to be irradiated this time has a shape as shown in FIG. 3, if the local shape 54 is formed in another portion, near field light based on the desired wavelength will be generated likewise in that portion.

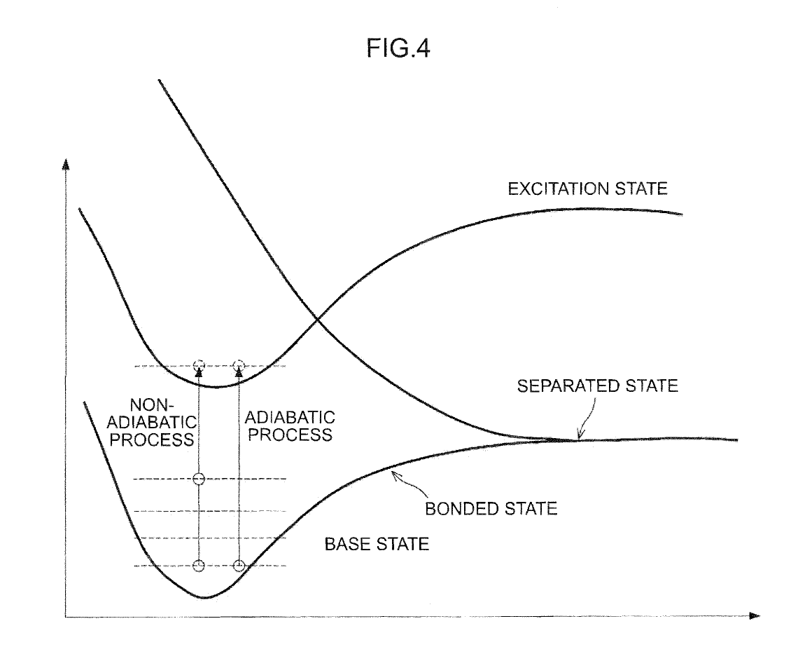

The generation of such near field light produces a non-adiabatic process to be explained below. FIG. 4 shows the conceptual diagram of the potential energy of the material for the N-type semiconductor 13. The state is stable with the internuclear distance of the atoms which constitute the material for the N-type semiconductor 13 being kept constant. However, the electrons in a molecular orbital are excited by photon energy.

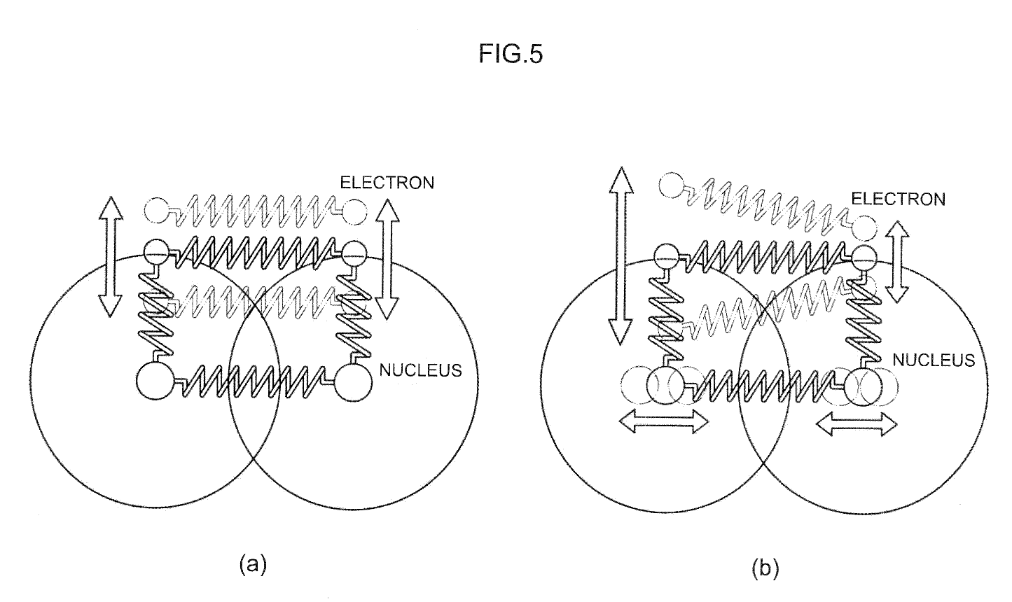

As shown in FIG. 5, the non-adiabatic process can be considered with a model showing the bonding of atoms in terms of springs. Because the wavelength of propagation light is generally much greater than a molecular size, with a molecular level, the field can be regarded as a spatially uniform electric field in the molecular level. As a result, as shown in FIG. 5(a), electrons adjoined by a spring are vibrated in the same amplitude and the same phase. Because the nucleus of the photosensitive resin film 12 is heavy, the nucleus cannot follow the vibration of the electrons, so that molecular vibration hardly occurs in the propagation light. Because association of molecular vibration with an electronic excitation process in propagation light can be neglected, the process is called “adiabatic process” (see Non-patent Document 1).

The spatial electric field gradient of near field light falls very sharply. Accordingly, near field light causes different vibrations to adjacent electrons, so that as shown in FIG. 5(b), a heavy nucleus is also vibrated by the different electron vibrations. Because near field light causing molecular vibration is equivalent to energy taking the form of molecular vibration, near field light can ensure the excitation process (non-adiabatic process) through a vibrational level as shown in FIG. 4. Because, in the excitation process through the nuclear vibrational level, a nucleus moves in response to the vibration, the excitation process is called “non-adiabatic process” in comparison with the adiabatic process which is the normal optical response (see Non-patent Document 1). In the non-adiabatic process, electrons are excited through the vibrational level, as shown in FIG. 4, it is possible to excite even light of the desired wavelength which is longer than the absorption wavelength of the material to be deposited to the excitation state, thereby generating electrons.

As apparent from the above, near field light is generated in the local shape 54, and is thus excited to the excitation state in the local shape 54 based on the non-adiabatic process. In the non-adiabatic process, even light of low energy, i.e., light of the desired wavelength which is longer than the absorption wavelength of the material to be deposited can be excited in the excitation process through the vibrational level. This makes it possible to selectively generate electrons only in the local shape 54.

When electrons are locally generated in the local shape 54 this way, the generated electrons can cancel generation of a local electric field based on the reverse bias voltage in the local shape 54. Hereinafter, the flow of generating electrons in the local shape 54 through the non-adiabatic step based on such near field light, and cancelling generation of a local electric field in the local shape 54 based on the generated electrons is called “non-adiabatic flow”. During the deposition step, continuous irradiation of light of the desired wavelength causes a non-adiabatic flow in the local shape 54 continuously, so that electrons are continuously generated in the local shape 54. As a result, generation of a local electric field in the local shape 54 can be cancelled by the electrons.

Since the non-adiabatic flow occurs in the local shape 54 to cancel a local electric field, it is possible to prevent the particles 51 constituting the material for the N-type semiconductor 13 from being adsorbed in the local shape 54. As a result, the particles 51 are not adsorbed in the local shape 54, so that the local shape 54 keeps the shape until the deposition step is completed.

Thus, according to the light receiving element fabricating method to which the invention is applied, the aforementioned non-adiabatic flow and particle adsorbing flow are continuously carried out, and the local shape 54 is sequentially formed on the surface of the material to be deposited.

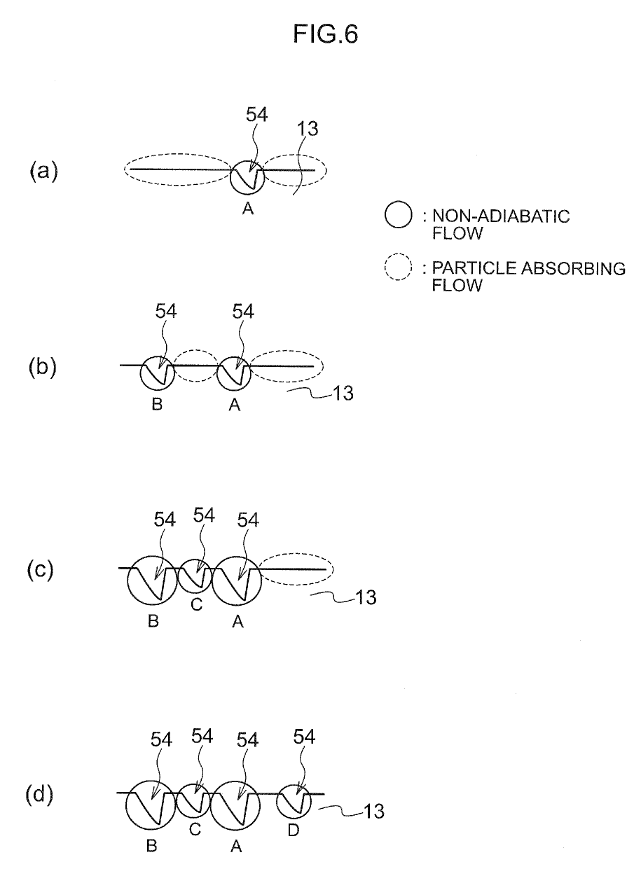

When the local shape 54 is accidentally formed in a portion A, as shown in FIG. 6(a), the non-adiabatic flow will progress in the portion A, cancelling a local electric field. Because the local shape 54 is not formed except in the portion A, the particles 51 are sequentially deposited based on the particle adsorbing flow.

Next, when the local shape 54 is accidentally formed in a portion B as a result of continuous deposition of the particles 51 in the portion B based on the particle adsorbing flow as shown in FIG. 6(b), the flow shifts to the non-adiabatic flow to cancel a local electric field. As a result of repetitive occurrence of the non-adiabatic flow in the portions A and B, cancellation of a local electric field is carried out continuously, thus preventing adsorption of the particles 51. As a result, the portions A and B keep the local shape 54. During this process, the particle adsorbing flow keeps progressing in other portions than the portions A and B.

Next, when the local shape 54 is accidentally formed in a portion C as a result of deposition of the particles 51 in the portion C based on the particle adsorbing flow as shown in FIG. 6(c), the flow shifts to the non-adiabatic flow to cancel a local electric field. As a result of repetitive occurrence of the non-adiabatic flow in the portion C as in the portions A and B, cancellation of a local electric field is carried out continuously to prevent adsorption of the particles 51. As a result, the portion C, like the portions A and B, keeps the local shape 54. During this process, the particle adsorbing flow keeps progressing in other portions than the portions A, B and C.

Next, when the local shape 54 is accidentally formed in a portion D as a result of continuous deposition of the particles 51 in portion D based on the particle adsorbing flow as shown in FIG. 6(c), the flow shifts to the non-adiabatic flow to cancel a local electric field. As a result of repetitive occurrence of the non-adiabatic flow in the portion D, cancellation of a local electric field is carried out continuously to prevent adsorption of the particles 51.

The local shape 54 is formed on the surface of the material to be deposited this way. Eventually, multiple local shapes 54 are formed on the surface of the N-type semiconductor 13 which has completed the deposition step.

When photoelectric conversion is actually performed with the light receiving element 1 fabricated by the light receiving element fabricating method to which the invention is applied, the reverse bias voltage is applied to the first electrode 12 and the second electrode 15 with the N type side serving as the positive voltage and the P type side serving as the negative voltage, and light to be received is irradiated on the depletion layer which is formed in the PN junction. When light of the desired wavelength enters the light receiving element 1 at this time, near field light is generated in the local shape 54. This is because, as mentioned above, the local shape 54 can generate near field light more effectively when light of the desired wavelength is irradiated.

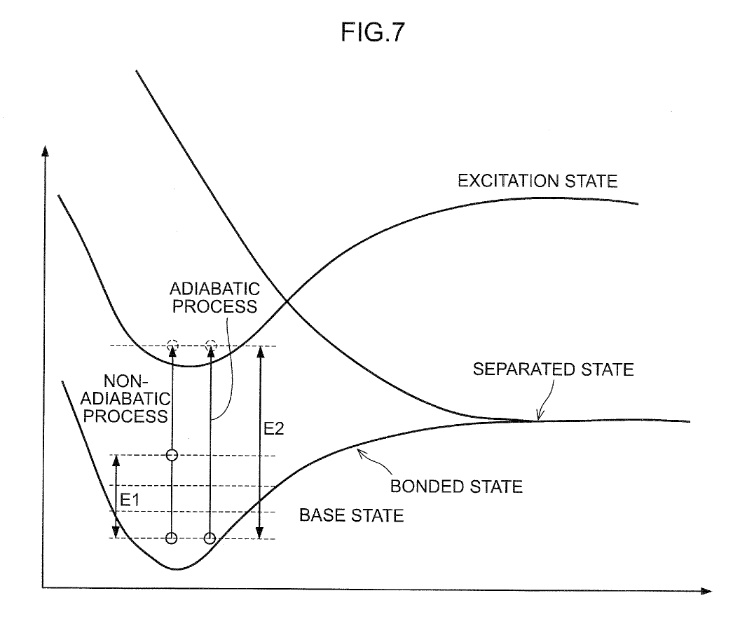

When the near field light is generated, the non-adiabatic process occurs. When the energy gap of the light receiving element 1 is E2, as shown in FIG. 7, the energy E1 of the desired wavelength cannot excite the light to the excitation level at all in the normal adiabatic process, failing to achieve photoelectric conversion. On the other hand, when the non-adiabatic process based on the near field light occurs, the light can be excited to the excitation level through multistage transition even if the energy E1 of the desired wavelength is less than the energy gap E2, and can thus be received by the light receiving element 1. This means that the light receiving element 1 can receive light of the desired wavelength longer than the wavelength which can be received by the light receiving element 1.

According to the light receiving element fabricating method to which the invention is applied, when it is desirable to fabricate a light receiving element which is provided with a sensitivity to a certain specific wavelength, a light receiving element which can receive light of the desired wavelength can be fabricated by irradiation of light having the specific wavelength as the desired wavelength. Therefore, according to the invention, a light receiving element provided with a sensitivity to a specific wavelength can be easily fabricated without selecting a material for the element.

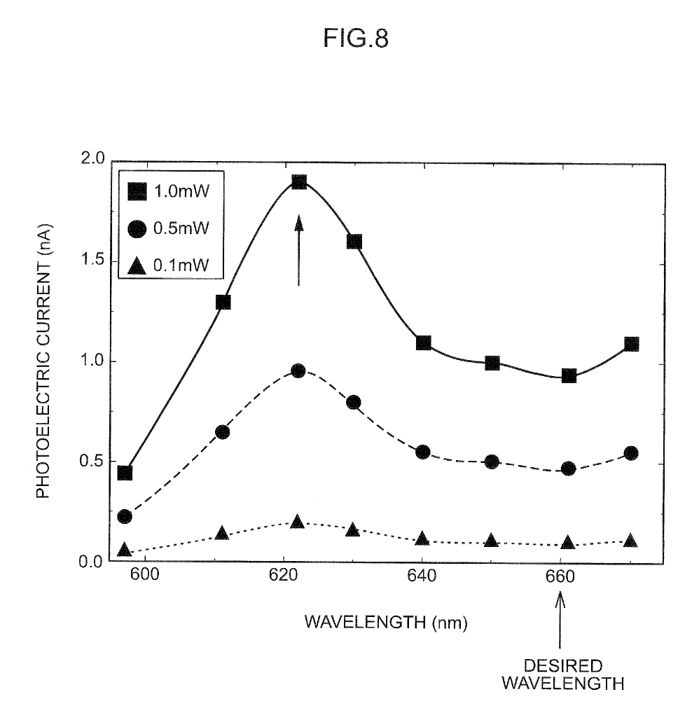

FIG. 8 shows the wavelength dependency on the photoelectric current of a light receiving element 1 fabricated by the light receiving element fabricating method to which the invention is applied. The individual plots represent cases where the light intensity of incident light is set to 0.1 mW, 0.5 mW, and 1.0 mW, respectively. The abscissa represents the wavelength and the ordinate represents the photoelectric current. When light of the desired wavelength of 660 nm was irradiated, the peak of the photoelectric current received was 620 nm. It can be therefore contemplated that near field light occurred in the local shape 54, causing the non-adiabatic process, so that the light of the desired wavelength of 660 nm was received as light of a low wavelength around the wavelength of 620 nm.

Although the foregoing description of the embodiment has been given of the case where the material constituting the N-type semiconductor 13 is deposited by sputtering, the embodiment is not limited to the case, and a similar technical concept may be adapted to a case of depositing a material for the P-type semiconductors 14 or each electrode 12, 15.

Deposition methods, such as MBE (Molecular Beam Epitaxy) and CVD (Chemical Vapor Deposition), other than sputtering can be naturally employed.

### DESCRIPTION OF REFERENCE NUMERALS

1 Light receiving element
3 Sputtering
11 Substrate
12 First electrode
13 N-type semiconductor
14 P-type semiconductor
15 Second electrode
17 Power supply
31 Chamber
32 Table
34 Target
35 Electrode
36 Power supply
37 Optical oscillator
51 Particles
54 Local shape

1. A method of fabricating a light receiving element having a PN junction of a P-type semiconductor and an N-type semiconductor joined together, and electrodes connected to the P-type semiconductor and the N-type semiconductor, respectively, the method comprising:
a deposition step of depositing a material for constituting one of the P-type semiconductor, the N-type semiconductor and the electrodes while applying a reverse bias voltage and irradiating light of a desired wavelength longer than an absorption wavelength of the material to be deposited,
wherein the deposition step has:
a non-adiabatic flow of, at a portion where a local shape to enable generation of near field light is formed on a surface of the deposited material with irradiation light of the desired wavelength, absorbing the irradiation light of the desired wavelength through a non-adiabatic process with the near field light generated in the local shape, thereby generating electrons, and canceling generation of a local electric field based on the reverse bias voltage in the local shape with the generated electrons in succession, and
a particle adsorbing flow of, at a portion where the local shape is not formed, causing the portion where the local electric field based on the reverse bias voltage is generated to sequentially adsorb particles forming the material, and shifting to the non-adiabatic flow when the local shape is formed through the adsorption process.

2. The method according to claim 1, wherein the non-adiabatic flow and the particle adsorbing flow are continuously performed to sequentially form the local shape on the surface of the deposited material.

3. A light receiving element fabricated by the method according to claim 1.

4. An apparatus for fabricating a light receiving element having a FN junction of a P-type semiconductor and an N-type semiconductor joined together, and electrodes connected to the P-type semiconductor and the N-type semiconductor, respectively, the apparatus comprising:
voltage application means for applying reverse bias voltage on a material for constituting one of the P-type semiconductor, the N-type semiconductor and the electrodes; and
deposition means for depositing a material while irradiating light of a desired wavelength longer than an absorption wavelength of the material to be deposited,
wherein the deposition means performs:
a non-adiabatic flow of, at a portion where a local shape to enable generation of near field light is formed on a surface of the deposited material with irradiation light of the desired wavelength, absorbing the irradiation light of the desired wavelength through a non-adiabatic process with the near field light generated in the local shape, thereby generating electrons, and canceling generation of a local electric field based on the reverse bias voltage in the local shape with the generated electrons in succession, and
a particle adsorbing flow of, at a portion where the local shape is not formed, causing the portion where the local electric field based on the reverse bias voltage is generated to sequentially adsorb particles forming the material, and shifting to the non-adiabatic flow when the local shape is formed through the adsorption process.

5. A light receiving element fabricated by the method according to claim 2.
